(19) United States
(12) Patent Application Publication
(10) Pub. No.: US 2026/0205093 A1
(43) Pub. Date: Jul. 16, 2026

(54) SURFACE ACOUSTIC WAVE DEVICE WITH HEAVY METAL ELECTRODE STACK

(71) Applicant: Qorvo US, Inc., Greensboro, NC (US)

(72) Inventors: Christian Huck, Munich (DE); Marc Solal, Longwood, FL (US); Casey Kirkpatrick, Jamestown, NC (US); Patrik Rath, Munich (DE); Sebastian Huebner, Munich (DE)

(21) Appl. No.: 19/136,147

(22) PCT Filed: Nov. 16, 2023
(86) PCT No.: PCT/US2023/079953

§ 371 Date: Jun. 5, 2025

Related U.S. Application Data
(60) Provisional application No. 63/435,083, filed on Dec. 23, 2022.

(51) Int. Cl. H03H 9/145; H03H 3/08; H03H 9/02

(52) U.S. Cl. CPC H03H 9/14541; H03H 3/08; H03H 9/02559; H03H 9/02834

(57) ABSTRACT

A surface acoustic wave, SAW, device comprises a piezo-electric substrate (12) with at least one electrode (20A, 20b) on a top surface of the piezoelectric substrate. The electrode is formed from an electrode stack (40) comprising a first heavy metal layer (42) formed from a heavy electrode metal and a first conducting layer (44) formed from a conducting material stacked over one another.

### FIELD OF THE DISCLOSURE

The present disclosure relates to acoustic wave devices, and particularly to surface acoustic wave (SAW) devices.

### BACKGROUND

Acoustic wave devices are widely used in modern electronics. At a high level, acoustic wave devices include a piezoelectric material in contact with one or more electrodes. Piezoelectric materials acquire a charge when compressed, twisted, or distorted, and similarly compress, twist, or distort when a charge is applied to them. Accordingly, when an alternating electrical signal is applied to the one or more electrodes in contact with the piezoelectric material, a corresponding mechanical signal (i.e., an oscillation or vibration) is transduced therein. Based on the characteristics of the one or more electrodes on the piezoelectric material, the properties of the piezoelectric material, and other factors such as the shape of the acoustic wave device and other structures provided on the device, the mechanical signal transduced in the piezoelectric material exhibits a frequency dependent on the alternating electrical signal. Acoustic wave devices leverage this frequency dependence to provide one or more functions.

Surface acoustic wave (SAW) devices, such as SAW resonators and SAW filters, are used in many applications such as radio frequency (RF) filters. For example, SAW filters are commonly used in wireless receiver front ends, duplexers, and receive filters. The widespread use of SAW filters is due to, at least in part, the fact that SAW filters exhibit low insertion loss with good rejection, can achieve broad bandwidths, and are a small fraction of the size of traditional cavity and ceramic filters. As the use of SAW filters in modern RF communication systems continues, there is a need for SAW filters with sharp transitions between desired passband frequencies and frequencies that are outside of desired passbands as well as the need to reduce the size of the SAW devices while maintaining and/or improving their performance.

### SUMMARY

A surface acoustic wave (SAW) device comprises a piezoelectric substrate with at least one electrode on a top surface of the piezoelectric substrate. The electrode is formed from an electrode stack comprising a first heavy metal layer formed from a heavy electrode metal and a first conducting layer formed from a conducting material stacked over one another.

In certain embodiments, the electrical resistivity of the conducting material is less than that of the heavy electrode metal.

In certain embodiments, a thickness of the heavy metal layer is greater than 20 percent of a thickness of the electrode stack.

In certain embodiments, a mass density of the conducting material is greater than 3.0 grams/cm³.

In certain embodiments, the heavy electrode material is selected from at least one of platinum (Pt), tungsten (W), gold (Au), iridium (Ir), rhodium (Rh), rhenium (Re), silver (Ag), Osmium (Os), Rhutenium (Ru), and an alloy comprising Pt, W, Au, Ir, Rh, Re, Os, Ru, and Ag.

In certain embodiments, the conducting material is selected from at least one of copper (Cu), Ag, Au, and an alloy comprising Cu, Ag, and Au.

In certain embodiments, the conducting material is selected from at least one of aluminum (Al) and an alloy comprising Al.

In certain embodiments, the SAW device is configured such that:
an electrical resistivity of the conducting material is less than that of the heavy electrode metal;
a thickness of the heavy metal layer is greater than 20 percent of a thickness of the electrode stack; and
a mass density of the conducting material is greater than 3.0 grams/cm³.

In certain embodiments, the piezoelectric substrate has a cut angle in the range of 118 to 122 degrees YX.

In certain embodiments, the piezoelectric substrate has a cut angle of 120 degrees YX.

In certain embodiments, the piezoelectric substrate is formed from lithium niobate with a cut angle in the range of 118 to 122 degrees YX or lithium tantalate with a cut angle in the range of 0 -50 degrees.

In certain embodiments, the SAW device comprises a first piston mode rail and a second piston mode rail, wherein:
the at least one electrode comprises first electrode with a first plurality of fingers and a second electrode with a second plurality of fingers, arranged to provide an interdigitated transducer;
the first piston mode rail extends over transverse ends of the first plurality of fingers; and
the second piston mode rail extends over transverse ends of the second plurality of fingers.

In certain embodiments, the first piston mode rail and the second piston mode rail may each be formed from a heavy piston mode rail material.

In certain embodiments, a duty factor associated with the first electrode and the second electrode is at least 55 percent.

In certain embodiments, an overcoat layer may be provided over the first electrode, the second electrode, and portions of the top surface of the piezoelectric substrate, wherein the first piston mode rail and the second piston mode rail reside in the overcoat layer.

In certain embodiments, the first heavy metal layer is over the first conducting layer in the electrode stack. The electrode stack may further comprise a second conducting layer over the first heavy metal layer. The electrode stack further comprises:
a first adhesion layer between the first conducting layer and the piezoelectric substrate;
a barrier layer between the first conducting layer and the first heavy metal layer; and
a second adhesion layer over the first heavy metal layer.

In one embodiment, in the electrode stack, the first conducting layer is over the first heavy metal layer. The electrode stack may comprise a second heavy metal layer over the first conducting layer and formed from a heavy electrode material. The electrode stack may comprise:
a first adhesion layer between the first heavy metal layer and the piezoelectric substrate;
a barrier layer between the first conducting layer and the first heavy metal layer; and
a second adhesion layer over the first conducting layer.

A method for fabricating a surface acoustic wave (SAW) device is also provided. The method may include:
providing a piezoelectric substrate; and
providing at least one electrode on a top surface of the piezoelectric substrate and formed from an electrode stack comprising a first heavy metal layer formed from a heavy electrode metal and a first conducting layer formed from a conducting material stacked over one another.

In another aspect, any of the foregoing aspects, and/or various separate aspects and features as described herein, may be combined for additional advantage. Any of the various features and elements as disclosed herein may be combined with one or more other disclosed features and elements unless indicated to the contrary herein.

In one embodiment, a resonator is provided with a heavy electrode over the piezoelectric substrate and a silicon oxide overlay over the heavy electrode, wherein the silicon oxide overlay is thicker than a 1.5 period.

The resonator may further include a substrate formed of lithium niobate with an orientation between 118 and 122 degrees XY wherein the heavy electrode is over the substrate.

The resonator may further include a substrate formed of lithium niobate with an orientation between 0 and 50 degrees XY wherein the heavy electrode is over the substrate.

The resonator may further include a slow region wherein a heavy metal is used on the slow region.

In one embodiment, a resonator is provided with a heavy electrode over the piezoelectric substrate and a silicon oxide overlay over the heavy electrode, wherein the silicon oxide overlay is thick enough to keep the acoustic energy on top of the overlay small. This avoids the need for the top surface to be free and results in a device that can work without being in a package with a cavity. An overlay thicker than two periods is appropriate. In some cases, a thickness thicker than three or four periods is appropriate.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a perspective view illustration of a representative surface acoustic wave (SAW) device.

FIG. 2 is a top view of the SAW device of FIG. 1 without piston mode rails.

FIG. 3 is a cross-section view of a SAW device with an electrode stack of the related art.

FIG. 4 is a top view of the SAW device of FIG. 1 with piston mode rails.

FIG. 5 is a cross-sectional view of a SAW device according to a first embodiment of the disclosure.

FIG. 6 is a cross-sectional view of a SAW device according to a second embodiment of the disclosure.

FIG. 7 is a top view of the SAW device according to one embodiment of the disclosure.

FIG. 8 is a plot of velocity (Vs) versus frequency for conventional SAW devices and those that employ the improvements described herein.

FIG. 9 is a plot of electrode pitch (P) versus frequency for conventional SAW devices and those that employ the improvements described herein.

FIG. 10 is a plot of total static capacitance per area (Cₜₒₜ/A) versus frequency for conventional SAW devices and those that employ the improvements described herein.

FIG. 11 plots the conductance (real part of admittance Re(Y)), admittance(absolute value of admittance |Y|), and return loss (|S₁₁|) versus frequency for a larger conventional SAW resonator with a 2.47 micrometer pitch (P) and a roughly 18% shorter resonator that has a 2.05 micrometer pitch (P) and employs the improvements described herein.

FIGS. 12 and 13 illustrate further embodiments wherein the electrode stacks of the SAW devices have more than two primary layers and conducting metal layers alternate with heavy metal layers.

FIGS. 14A-14C and 15A-15C are graphs of simulations for an infinite silicon oxide overlay over various platinum thicknesses. Different substrate orientations are used resulting in different coupling factors.

FIG. 16 is a block diagram of a user element in which the concepts of the present disclosure may be employed.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The present disclosure relates to a surface acoustic wave (SAW) device comprising a piezoelectric substrate with at least one electrode on a top surface of the piezoelectric substrate. The electrode is formed from an electrode stack comprising a first heavy metal layer formed from a heavy electrode metal and a first conducting layer formed from a conducting material stacked over one another.

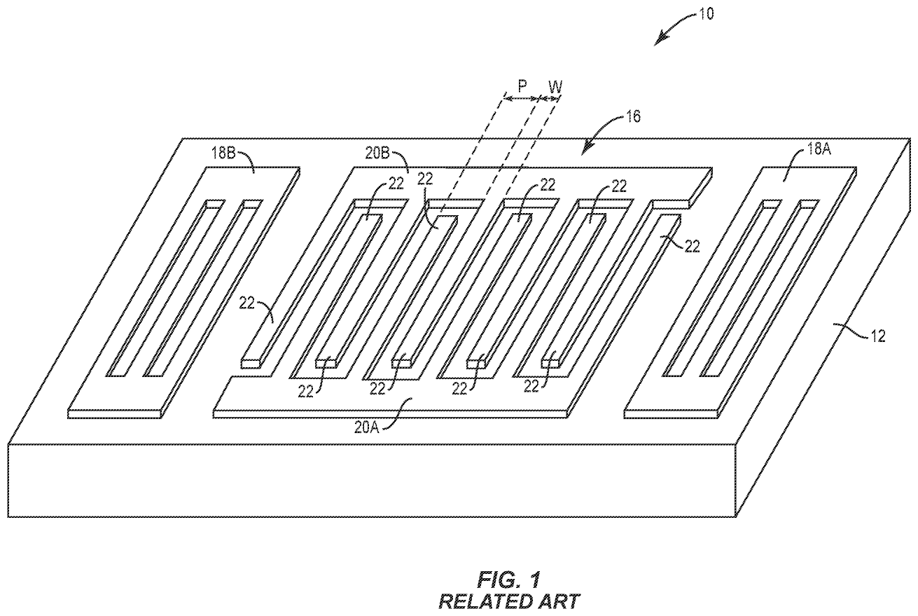

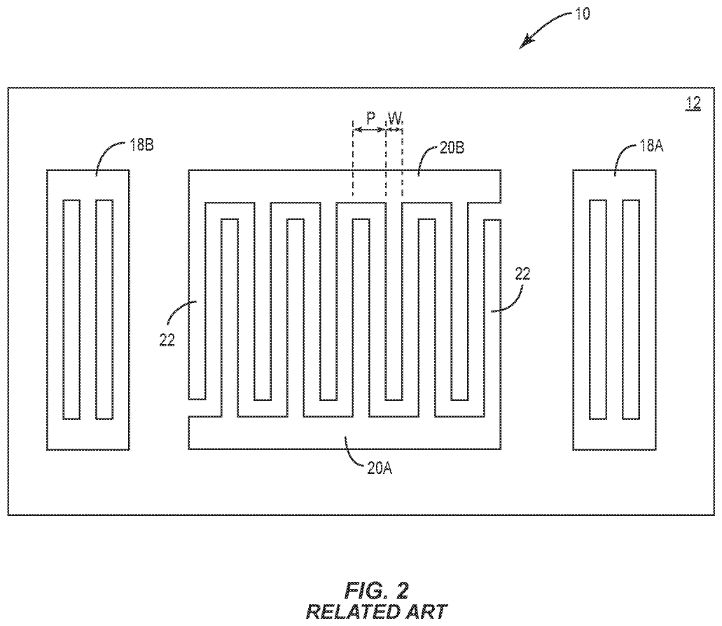

Before describing novel concepts of the present disclosure further, a general discussion of SAW devices is provided. FIGS. 1 and 2 are isometric and top views of a representative SAW device 10 of the related art. The SAW device 10 includes a piezoelectric substrate 12, an IDT 16 on a top surface of the piezoelectric substrate 12, a first reflector structure 18A on the top surface of the piezoelectric substrate 12 adjacent to the IDT 16, and a second reflector structure 18B on the top surface of the piezoelectric substrate 12 adjacent to the IDT 16 opposite the first reflector structure 18A. As it is well known, the resonator 10 may be connected to other resonators on a die to form a more complex device like a filter. Also, it is understood that FIGS. 1 and 2 are only simplified representations of SAW resonators. Real resonators may be more complicated. For example, the period between the electrodes or their polarity can vary along the transducer. In addition, only one-port resonators are represented, i.e. one transducer between two reflectors. It is well known that coupled resonator filters (CRF) can be designed by inserting several transducers between reflectors, these transducers being connected to separated electrical ports (typically input and output ports). It is also well known that several of these CRF may be connected together or connected to one-port resonators to form a device (normally a filter or a duplexer). Even if these devices are not specifically described, it is understood that they are within the scope of the present disclosure.

The IDT 16 includes a first electrode 20A and a second electrode 20B, each of which includes a number of electrode fingers 22 that are interleaved with one another as shown. A lateral distance between adjacent electrode fingers 22 of the first electrode 20A and the second electrode 20B defines an electrode pitch P of the IDT 16. The electrode pitch P may at least partially define a center frequency wavelength A of the SAW device 10, where the center frequency is the primary frequency of mechanical waves generated in the piezoelectric substrate 12 by the IDT 16. A finger width W of the adjacent electrode fingers 22 over the electrode pitch P may define a metallization ratio, or duty factor (DF), of the IDT 16, which will dictate certain operating characteristics of the SAW device 10, as will be appreciated by those skilled in the art.

In operation, an alternating electrical input signal provided at the first electrode 20A is transduced into a mechanical signal in the piezoelectric substrate 12, resulting in one or more acoustic waves therein. In the case of the SAW device 10, the resulting acoustic waves are predominately surface acoustic waves. As discussed above, due to the electrode pitch P, the metallization ratio of the IDT 16, the characteristics of the material of the piezoelectric substrate 12, and other factors, the magnitude and frequency of the acoustic waves transduced in the piezoelectric substrate 12 are dependent on the frequency of the alternating electrical input signal. This frequency dependence is often described in terms of changes in the impedance and/or a phase shift between the first electrode 20A and the second electrode 20B with respect to the frequency of the alternating electrical input signal.

An alternating electrical potential between the first and second electrodes 20A and 20B creates an electrical field in the piezoelectric material which generates acoustic waves. The acoustic waves travel at the surface and eventually are transferred back into an electrical signal between the first and second electrodes 20A and 20B. The first reflector structure 18A and the second reflector structure 18B reflect the acoustic waves in the piezoelectric substrate 12 back towards the IDT 16 to confine the acoustic waves in the area surrounding the IDT 16. FIG. 2 is a top view of the SAW device 10.

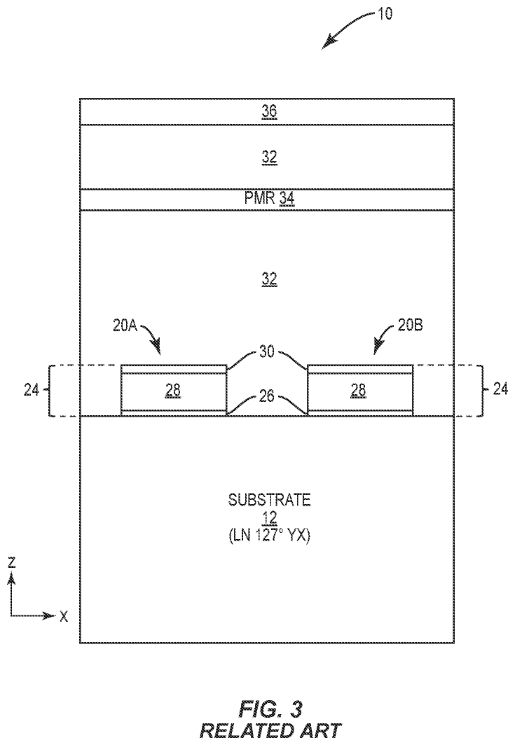

FIG. 3 is a cross-sectional view of a SAW device 10 wherein the first and second electrodes 20A and 20B are formed from a more conventional electrode stack 24. The conventional electrode stack 24 is shown with a first adhesion layer 26 on the piezoelectric substrate 12, a conducting metal layer 28 on the first adhesion layer 26, and a second adhesion layer 30 on the conducting metal layer 28. In one exemplary configuration, the first adhesion layer 26 is titanium (Ti), the conducting metal layer 28 is Cu, and the second adhesion layer 30 is Al. The first and second adhesion layers 26, 30 facilitate adhesion of adjacent layers. If the piezoelectric substrate is lithium niobate, LiNbO₃ (LN), the piezoelectric cut angle is generally close to 127 degrees YX. This means that the substrate orientation is defined by starting from a plane with a normal which is the Y axis of the crystal and rotating this axis by 127 degrees around the X axis of the crystal.

One or more dielectric overcoat layers 32 are provided over the first and second electrodes 20A and 20B and remaining portions of the piezoelectric substrate 12. The dielectric overcoat layer(s) 32 provides a temperature compensation layer to improve temperature stability by its positive temperature coefficient of frequency (TCF) that compensates for the negative TCF of the piezoelectric substrate 12 and other materials in the SAW device 10. The dielectric overcoat layer(s) 32 may be formed from silicon dioxide (SiO₂), doped SiO2, or the like.

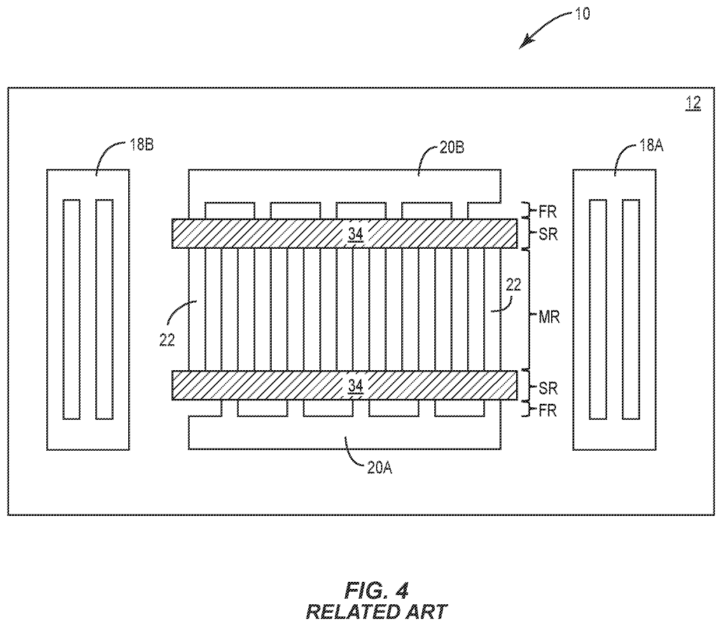

Elongated piston mode rails (PMRs) 34 may be buried in the dielectric overcoat layer 32 or provided between dielectric overcoat layers 32 in areas that extend over the transverse ends of the fingers 22 of the first and second electrodes 20A and 20B. The areas over which the PMRs 34 are provided are more clearly illustrated in FIG. 4, which is a top view of the SAW device 10 in which the dielectric overcoat layer 32 is not shown. The PMRs 34 function is to enable piston mode operation with better transverse mode suppression. A slow region (SR) with relatively slower acoustic wave velocities is provided beneath the PMRs 34. A fast region (FR) with relatively faster acoustic wave velocities is provided outside of the slow regions (SRs). A main region (MR) is provided between the slow regions (SRs) and the fast regions (FRs). The main region (MR) has the desired acoustic wave velocities, which are generally between the slower and faster acoustic wave velocities of the slow regions (SRs) and fast regions (FRs). The presence of a large enough fast region results in the guiding of the acoustic waves in the resonator and thus avoids energy leakage but also results in the presence of transverse modes. The presence of the slow regions essentially results in one of the guided modes having a rectangular shape and being the only one (or almost) to be excited. As is known to those skilled in the art, other implementations are possible to obtain the same results. For example, the slow region can be realized by adding extra metal on the electrode in the region 34 and/or increasing the duty factor in this region. Several of these implementations may be combined to obtain the desired result.

A passivation layer 36 may be formed over the dielectric overcoat layer 32 for passivation and/or trimming. The passivation layer 36 may be formed from SiO₂, Si₃N₄, or the like

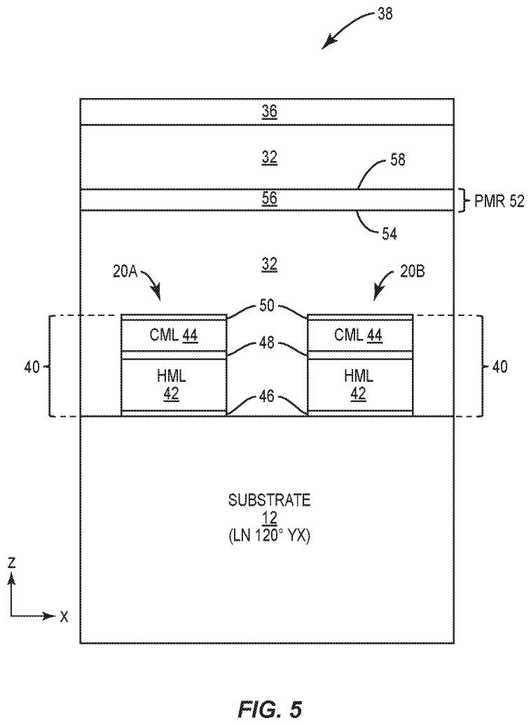

The concepts provided herein provided novel improvements on the conventional electrode stack 24 as well as the PMR 34 described above. These improvements are described with initial reference to FIG. 5, which depicts an exemplary embodiment of a modified SAW device 38. Notably, the conventional electrode stack 24 for the first and second electrodes 20A and 20B is replaced with an electrode stack 40 that includes both a heavy metal layer (HML) 42 and a conducting metal layer (CML) 44.

The heavy metal layer 42 is a layer formed from a heavy electrode material. A heavy electrode material is defined as a metal or alloy that has a mass density higher than 10.28 grams/cm³ , while exhibiting properties of a metal and/or having some electrical conductivity. For reference, molybdenum (Mo) has a mass density of 10.28 grams/cm³ . In one embodiment, thickness of the heavy metal layer 42 is at least 20%, at least 30%, or at least 40% of the total thickness of the electrode stack 40. Exemplary, but non-limiting heavy electrode materials for the heavy metal layer 42 include Pt, W, Au, Ir, Rh, Re, Os, Ru, Ag, or any alloy including Pt, W, Au, Ir, Rh, Re, Os, Ru, and/or Ag. In certain, embodiments, the duty factor (DF) of the electrodes 20A and 20B is at least 55%, at least 65%, or at least 75%.

A conducting metal layer 44 is a layer formed from a conducting material, which is defined by a metal with a resistivity lower than 1e-7 Ohm*m. In one embodiment, the conducting metal layer 44 is formed from a conducting material that has an electrical resistivity lower than the heavy electrode material of the heavy metal layer 42. In certain embodiments, the mass density of the conducting material of the conducting metal layer 44 is greater than 3.0 g/cm³, greater than 5.0g/cm³ , less than the mass density of the heavy electrode material of the heavy metal layer 42, or a combination thereof. Exemplary, but non-limiting, conducting materials for the conducting metal layer 44 may include Cu, Ag, Au, Al, or any alloy including Cu, Ag, Au, and/or Al. In certain embodiments, the conducting material for the conducting metal layer 44 is more conductive than the heavy electrode material of the heavy metal layer 42. Other options include alloying of high mass density metals in electrode or piston mode rails stacks for material hardening to increase robustness and power handling (i.e. alloying Pt by addition of e.g. Ag, Au, Cu, Co, Cr, Fe, Ga, Ge, In, Mg, Mn, Mo, Ni, Si, Sn, Ta, Ti, V, W or Zr).

As illustrated, the electrode stack 40 has a first adhesion layer 46 on or directly on the piezoelectric substrate 12. The heavy metal layer 42 resides on or directly on the first adhesion layer 46. A barrier layer 48 resides on or directly on the heavy metal layer 42. The conducting metal layer 44 resides on or directly on the barrier layer 48, and a second adhesion layer 50 resides over the conducting metal layer 44.

The first and second adhesion layers 46, 50 may be formed from Ti, chromium (Cr), Nickel (Ni), and the like or any alloy of/with them and function to provide good adhesion with adjacent layers. The barrier layer 48 may be formed from Ti, Cr, Ni, and the like or any alloy of/with them and function to reduce or avoid material diffusion between the heavy metal layer 42 and the conducting metal layer 44 of the electrode stack 40.

In one exemplary embodiment, the following configuration of the SAW device 38 is provided. Notably, for the thickness ranges, alternate ranges are provided in parentheticals; however, these ranges are merely exemplary and not intended to limit the scope of the disclosure or the claims that follow, unless specifically stated. The piezoelectric substrate 12 may be lithium niobate with a cut angle in the range of 118° YX to 122° YX, In one embodiment, the cut angle is 120° YX. The piezoelectric substrate 12 may also be lithium niobate with a cut angle in the range of 0° YX to 50° YX,

The adhesion layer 46 is in direct contact with the piezoelectric substrate 12 and formed from Ti with thickness between 100-200 Å. The heavy metal layer 42 is formed from Pt with thickness 3500-4500 Å (2500-5500 Å). The barrier layer 48 is also Ti with a thickness in the range of 200-400 Å (100-500 Å). The conducting metal layer 44 is Cu with a thickness in the range of 1000-2000 Å (500-2500 Å). In certain embodiments, Cu may be preferable to Al due to its better electrical conductivity and higher mass density; however, other embodiments may employ Al. The top adhesion layer 50 is Ti with a thickness in the range of 100-200 Å (50-300 Å).

The dielectric overcoat layer 32 is SiO₂ with a thickness, as measured from the top of the electrode stack 40 to the bottom of the piston mode rail 52, in the range of 6500-7500 Å (5000-9000 Å). The piston mode rail 52 has bottom and top layers 54, 56 formed of Ti with a thickness in the range of 100-200 Å (50-300 Å), and a middle layer 56 formed of Cu with a thickness in the range of 800-1400 Å (500-2500 Å). The dielectric overcoat layer 32 has a thickness above the piston mode rail in the range of 2000-2600 Å (1500-3500 Å). The passivation layer 38 has a thickness in the range of 300-1900 Å (150-3000 Å). Also, it is worth mentioning that a high duty factor (DF) of the electrodes 22A and 22B (e.g. higher than 50%) is beneficial in certain embodiments for size reduction and to reduce electrical resistance of the electrodes. The materials and ranges are also applicable to the embodiments described below.

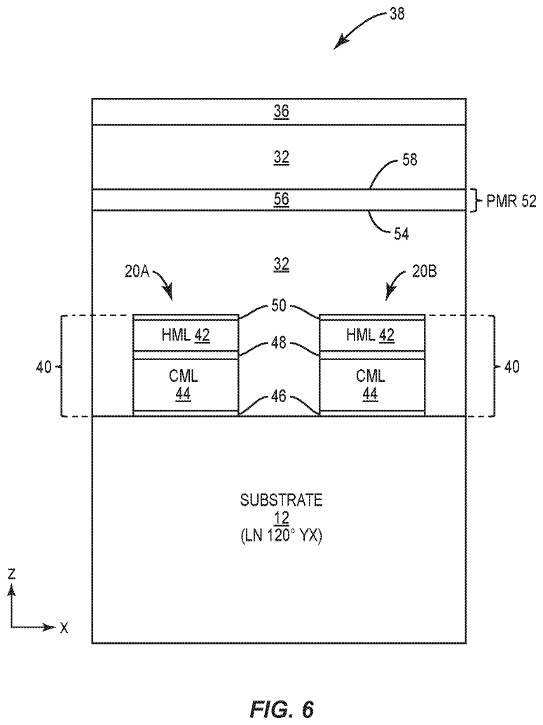

The conducting metal layer 44 and the heavy metal layer 42 may be swapped as illustrated in FIG. 6. For this embodiment, the electrode stack 40 has the first adhesion layer 46 on or directly on the piezoelectric substrate 12. The conducting metal layer 44 is lower in the electrode stack 40 and resides on or directly on the first adhesion layer 46. A barrier layer 48 resides on or directly on the conducting metal layer 44. The heavy metal layer 42 resides on or directly on the barrier layer 48, and the second adhesion layer 50 resides over the conducting metal layer 44.

As noted above, if the piezoelectric substrate 12 is lithium niobate, LiNbO₃ (LN), the piezoelectric cut angle of the piezoelectric substrate 12 may be changed to 120° YX +/−2°. The change in the cut angle from 127 degrees YX to approximately 120 degrees YX is provided to reduce the coupling to spurious shear horizontal mode. This coupling depends on the substrate orientation and on the electrode and oxide stack. For previous stacks, the spurious excitation was reduced for an orientation close to 127 degrees. When heavy electrodes are used, the spurious excitation is the smallest when the orientation is around 120 degrees.

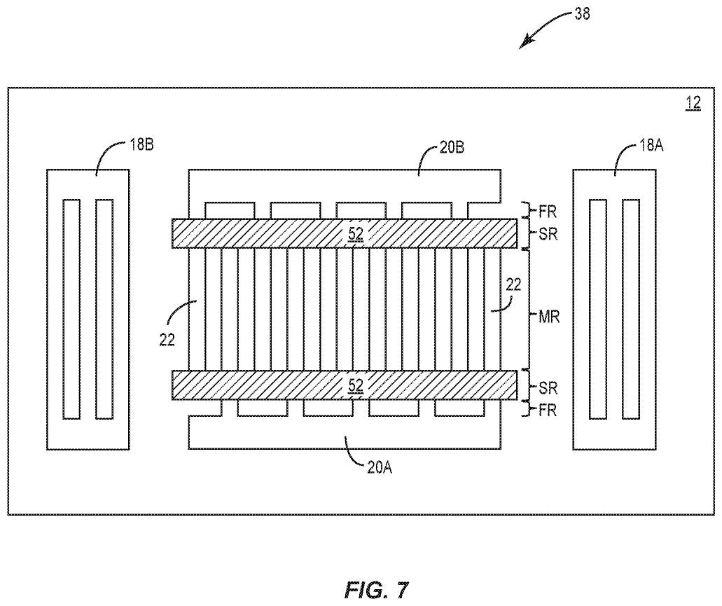

In certain embodiments, a new PMR 52 with an enhanced material stack may also be employed. The enhanced material stack of the PMR 52 may have one or more layers wherein one of the layers includes a heavy metal or alloy. In the illustrated embodiments, the PMR 52 has a lower layer 54, a middle layer 56 on or directly on the lower layer 54, and an upper layer 58 on or directly on the middle layer 56. The location of the PMR 52 is generally the same as that of the PMR 34 described above, as illustrated in FIGS. 6 and 7.

In one embodiment, one of the lower, middle, upper layers 54, 56, 58 may be formed from a heavy PMR material, which is defined as a metal material having a mass density greater than the mass density of Ti. In other embodiments, the mass density may be greater than 4.51 grams/cm³, greater than 5.5 grams/cm³, greater than 6.5 grams/cm³ or greater than 7.5 grams/cm³. For example, the middle layer 56 may be formed from a heavy PMR material while the adjacent lower and upper layers 54, 58 are adhesion layers. The heavy PMR material may have a mass density greater than the conducting material of the conducting metal layer 44 and less than the heavy metal material of the heavy metal layer 42. Exemplary, but non-limiting materials for the heavy PMR material include Os, Ir, Pt, Re, W, Au, Ru, Ag, Mo, Cu, Ni, Cr, and Zr and alloys of these materials.

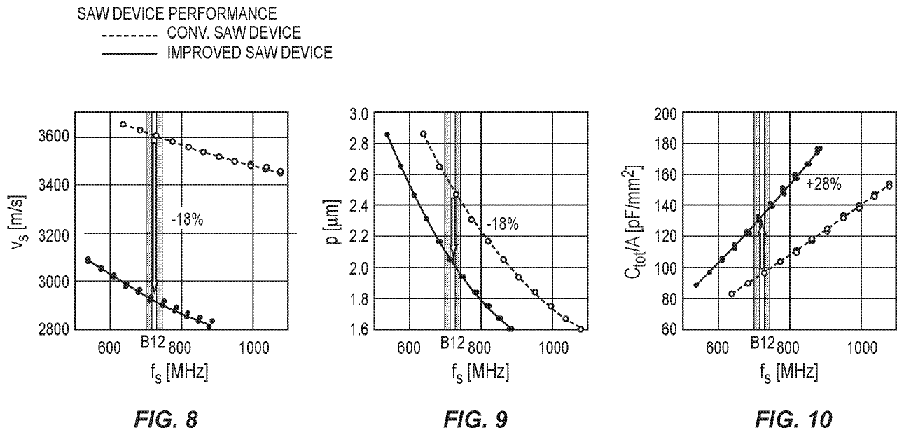

FIG. 8 is a plot of velocity (vₛ) at resonance frequency versus frequency for conventional SAW devices 10 and those that employ the improvements described above for SAW devices 38. The vertical lines define the band 12 (B12) frequency range of the Long Term Evolution (LTE) communication standards for mobile communications for the Transmit Uplink (Tx) and Receive Downlink (Rx) paths. With the improvements provided herein, the velocity of acoustic waves in the B12 frequency range decrease by approximately 18%. A reduction in velocity translates to being able to reduce the size of the SAW device 38.

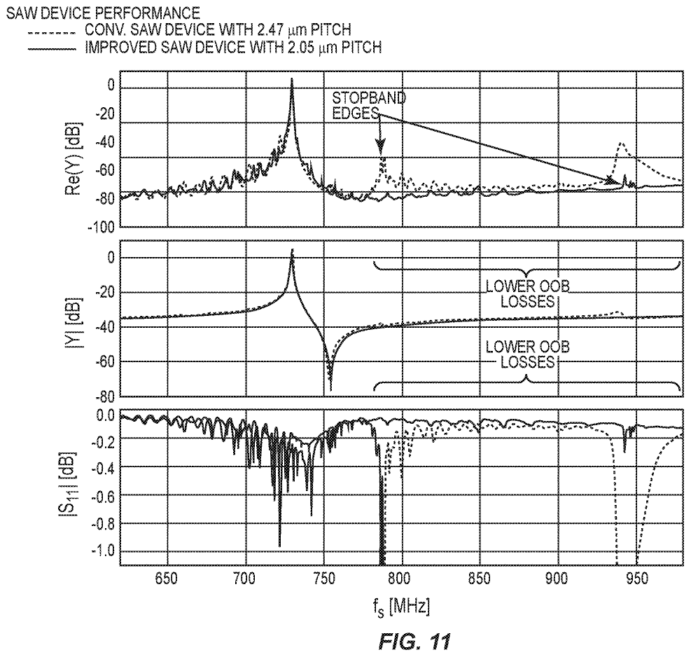

FIG. 9 is a plot of electrode pitch (P) versus frequency for conventional SAW devices 10 and those that employ the improvements described above for SAW devices 38. The vertical lines define the band 12 (B12) frequency range. With the improvements provided herein, the pitch of the fingers for the electrodes decreased by approximately 18%, which directly translates to a reduced size of the SAW device 38.

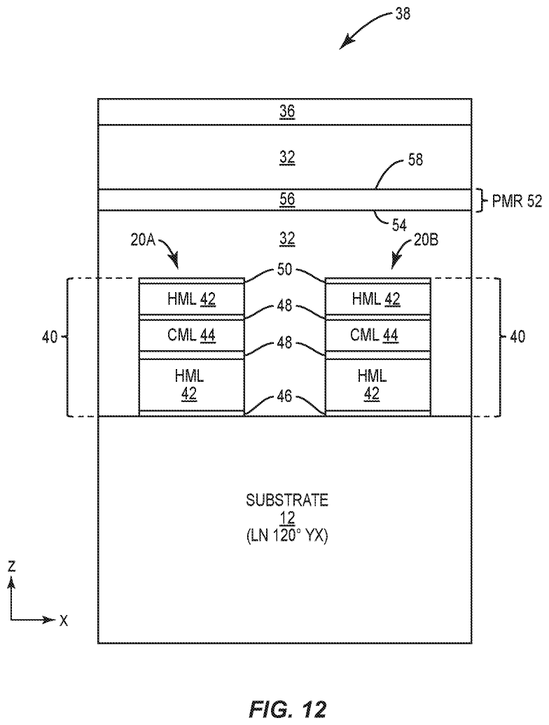

FIG. 10 is a plot of total static capacitance per area (Cₜₒₜ/A) versus frequency for conventional SAW devices 10 and those that employ the improvements described above for SAW devices 38. Increasing the total capacitance per area allows one to achieve a desired amount of capacitance in a smaller area. With the improvements provided herein, the total capacitance per area increased 28% for the band 12 (B12) frequency range.

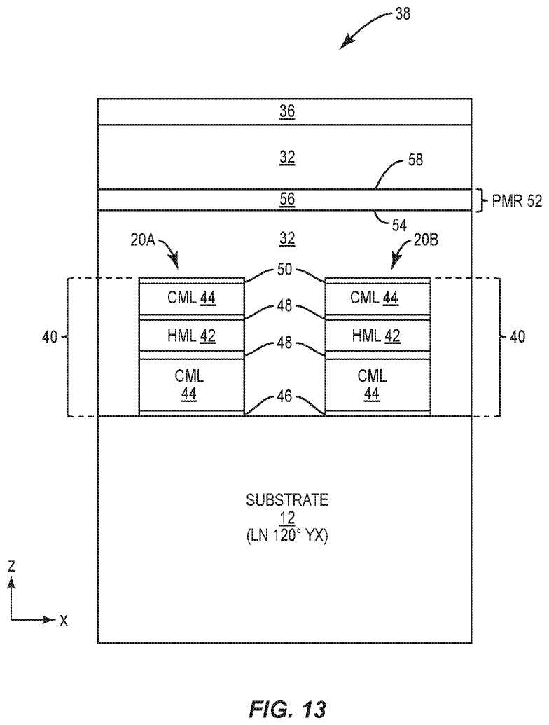

FIG. 11 plots the conductance (real part of admittance Re(Y)), admittance (absolute value of admittance |Y|) and return loss (|S₁₁|) versus frequency for larger conventional SAW resonators 10 with a 2.47 micrometer pitch (P) and a roughly 18% shorter resonator that has a 2.05 micrometer pitch (P) and employs the improvements described above. The 18% pitch reduction has an effect in both the longitudinal and transverse directions, because everything scales with pitch. The total area of the resonator would be ~33% (1-0.82*0.82) smaller. For completeness and accuracy, the required area for a specific capacitance is defined by the capacitance per area for each resonator and may differ from this coarse estimate based on velocities/pitch.

The reflectivity of the electrodes defines a stop-band in which the waves are reflected. For a synchronous resonator, the lower edge of this stop-band is very close to the resonance frequency. The upper edge of the stop-band causes a spurious which can be seen on the conductance. With the improved, yet smaller, SAW devices 38, the reflectivity is significantly higher while coupling and return losses are similar. The higher reflectivity (Re) is beneficial in that the upper stop band edges are moved much higher in the frequency range and further away from the series and parallel resonance frequencies. In fact, the out-of-band (OOB) losses are significantly better (i.e. lower) with the much smaller SAW devices 38, which include the enhancements described herein.

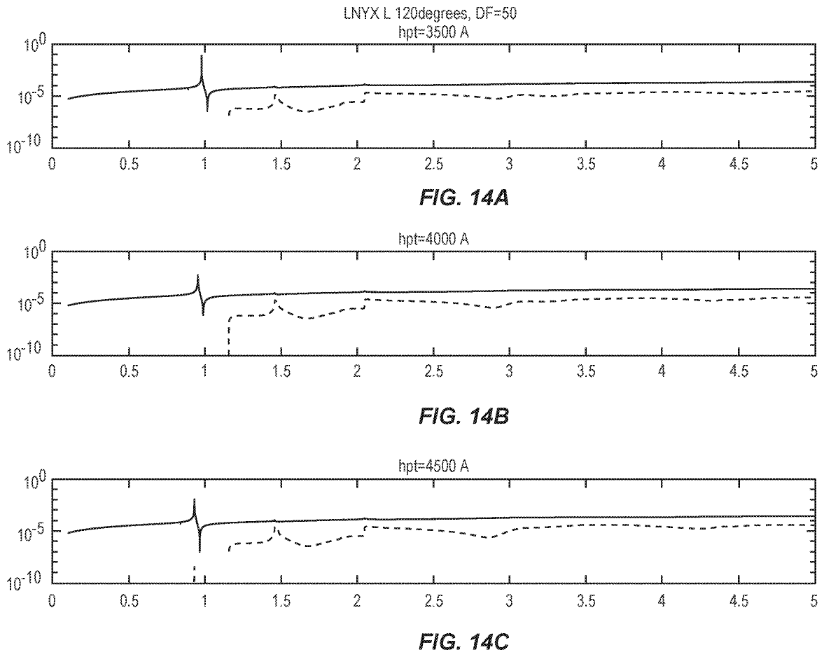

FIGS. 12 and 13 illustrate further embodiments wherein the electrode stacks 40 of the SAW devices 38 have more than two primary layers wherein conducting metal layers 44 alternate with heavy metal layers 42. FIG. 12 provides an electrode stack 40 wherein one conducting metal layer 44 is provided between two heavy metal layers 42. One barrier layer 48 is provided between the upper heavy metal layer 42 and the conducting layer 44, and another barrier layer 48 is provided between the lower heavy metal layer 42 and the conducting metal layer 44. Adding the upper heavy metal layer 42 may facilitate better small signal performance and manufacturability, e.g. for frequency trimming, and provide better large signal performance, greater power handling capability, longer lifetimes, and less non-linearities.

FIG. 13 provides an electrode stack 40 wherein one heavy metal layer 42 is provided between two conducting metal layers 42. One barrier layer 48 is provided between the upper conducting metal layer 44 and the heavy metal layer 42, and another barrier layer 48 is provided between the lower conducting metal layer 44 and the heavy metal layer 42.

The need for a cavity package may be suppressed by using a thick enough dielectric overlay. If this is the case, the acoustic energy is located at the interface between the piezoelectric substrate and the overlay. Typical overlay thicknesses are larger than 1 lambda or two electrode periods. In certain embodiments, the overlay thickness is greater than 1.5 lambda. In this case, one may choose electrodes heavy enough to reduce the resonance frequency below the bulk cutoff frequency and the overlay cutoff frequency. The solutions described for temperature compensated SAW (TC-SAW) devices work in this case. For example, electrodes comprising a film of heavy material and a film of conductive material like platinum-aluminum or platinum-copper or other options using tungsten or molybdenum are exemplary solutions. To suppress transverse modes, piston mode resonators are also possible, but may require a heavy material for the slow regions. Materials like copper, platinum, tungsten or gold are good materials. When lithium niobate (LN) is used, an orientation close to 120° is a beneficial orientation. Alternate orientations between Y and Y+50 give a larger coupling factor but are more sensitive to spurious modes.

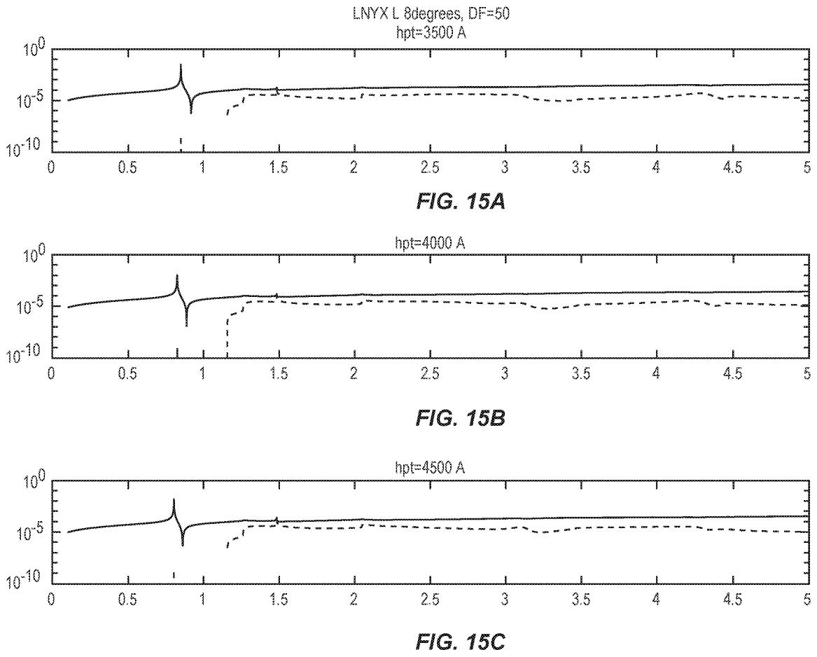

FIGS. 14A-14C and 15A-15C provide periodic simulations for an infinite silicon oxide overlay and various platinum thicknesses. The electrode is made of a platinum film and an aluminum film 1550 A thick. Thin titanium layers are used as adhesion layers between the substrate and the electrode and between the platinum and the aluminum. The electrode period is 1.6 um and the duty factor is 50%. The solid curve as shown in FIGS. 14A-14C and 15A-15C represents the admittance, and the dashed curve represents the conductance. Frequencies with a non 0 conductance (above about 1.1 GHz) are above the silicon oxide cutoff frequency, meaning a significant portion of the energy is lost in the oxide. The use of thick electrodes allows for pushing the resonance frequency below the cutoff frequency. For FIGS. 14A-14C, the lithium niobate orientation is approximately Y+120 degrees (e.g. between 118 and 122 degrees), and the coupling factor is about 8% for platinum thicknesses of 3500, 4000, and 4500 angstroms. This orientation provides a spurious free response. For FIGS. 15A-15C, the lithium niobate orientation is Y+8, and the coupling factor is about 16% for platinum thicknesses of 3500, 4000, and 4500 angstroms. This orientation also provides a spurious free response for these metal stacks. Solutions when the lithium niobate orientation is Y 0 to 50 degrees are also beneficial. Depending on the metal stack, the duty factor, and the overlay material, spurious free orientations vary in this 0 to 50 degrees range.

In certain embodiments, resonators with heavy electrode having a silicon oxide overlay thicker than 1.5, 2, 3, or 4 periods are provided. The lithium niobate orientation may be approximately 120 degrees, between 0 and 50 degrees, and the like. Further, a heavy metal may be provided in the slow region (e.g. piston mode resonator).

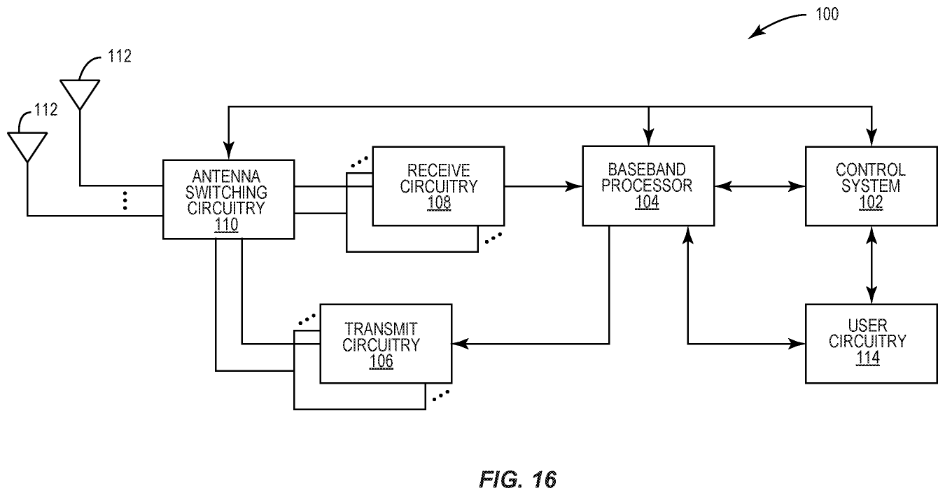

With reference to FIG. 16, the concepts described above may be implemented in various types of user elements 100, such as mobile terminals, smart watches, tablets, computers, navigation devices, access points, and like wireless communication devices that support wireless communications, such as cellular, wireless local area network (WLAN), Bluetooth, and near field communications. The user elements 100 will generally include a control system 102, a baseband processor 104, transmit circuitry 106, receive circuitry 108, antenna switching circuitry 110, multiple antennas 112, and user interface circuitry 112. In a non-limiting example, the control system 102 may be a field-programmable gate array (FPGA) or an application-specific integrated circuit (ASIC). In this regard, the control system 102 may include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter of the receive circuitry 108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed on greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal through the antenna switching circuitry 110 to the antennas 112. The multiple antennas 112 and the replicated transmit and receive circuitries 106, 108 may provide spatial diversity. Modulation and processing details will be understood by those skilled in the art. The SAW devices 10, 38 are particularly useful in the filters, duplexers and N-in-1 multiplexers that may be provided in the antenna switching circuitry 110, receive circuitry 108, and/or transmit circuitry 106.

Those skilled in the art will recognize improvements and modifications to the preferred embodiments of the present disclosure. All such improvements and modifications are considered within the scope of the concepts disclosed herein and the claims that follow.

1. A surface acoustic wave (SAW) device, comprising:
a piezoelectric substrate;
at least one electrode on a top surface of the piezoelectric substrate and formed from an electrode stack comprising a first heavy metal layer formed from a heavy electrode metal having a mass density higher than or equal to molybdenum and a first conducting layer formed from a conducting material stacked over one another.

2. The SAW device of claim 1 wherein an electrical resistivity of the conducting material is less than that of the heavy electrode metal.

3. The SAW device of claim 1 wherein a thickness of the heavy metal layer is greater than 20 percent of a thickness of the electrode stack.

4. The SAW device of claim 1 wherein a mass density of the conducting material is greater than 3.0 grams/cm³.

5. The SAW device of claim 1 wherein the heavy electrode material is selected from at least one of Pt, W, Au, Ir, Rh, Re, Os, Ru, Ag, and an alloy comprising Pt, W, Au, Ir, Rh, Re, Os, Ru, and Ag.

6. The SAW device of claim 1 wherein the conducting material is selected from at least one of Cu, Ag, Au, and an alloy comprising Cu, Ag, and Au.

7. The SAW device of claim 1 wherein the conducting material is selected from at least one of Al and an alloy comprising Al.

8. The SAW device of claim 1 wherein:
an electrical resistivity of the conducting material is less than that of the heavy electrode metal;
a thickness of the heavy metal layer is greater than 20 percent of a thickness of the electrode stack; and
a mass density of the conducting material is greater than 3.0grams/cm³.

9. The SAW device of claim 8 wherein:
the heavy electrode material is selected from at least one of Pt, W, Au, Ir, Rh, Re, Os, Ru, Ag, and an alloy comprising Pt, W, Au, Ir, Rh, Re, Os, Ru, and Ag; and
the conducting material is selected from at least one of Cu, Ag, Au, and an alloy comprising Cu, Ag, and Au.

10. The SAW device of claim 9 wherein the piezoelectric substrate has a cut angle in the range of 118 to 122 degrees YX.

11. The SAW device of claim 10 wherein the piezoelectric substrate has the cut angle of 120 degrees YX.

12. The SAW device of claim 1 further comprising a first piston mode rail and a second piston mode rail, wherein:
the at least one electrode comprises a first electrode with a first plurality of fingers and a second electrode with a second plurality of fingers, arranged to provide an interdigitated transducer;
the first piston mode rail extends over transverse ends of the first plurality of fingers; and
the second piston mode rail extends over transverse ends of the second plurality of fingers.

13. The SAW device of claim 12 wherein the first piston mode rail and the second piston mode rail are each formed from a heavy piston mode rail material.

14. The SAW device of claim 13 wherein a duty factor associated with the first electrode and the second electrode is at least 55 percent.

15. The SAW device of claim 13 further comprising an overcoat layer over the first electrode, the second electrode, and portions of the top surface of the piezoelectric substrate, wherein the first piston mode rail and the second piston mode rail reside in the overcoat layer.

16. The SAW device of claim 1 wherein the piezoelectric substrate has a cut angle in the range of 118 to 122 degrees YX.

17. The SAW device of claim 16 wherein the piezoelectric substrate is formed from lithium niobate.

18. The SAW device of claim 1 wherein the piezoelectric substrate has a cut angle of 120 degrees YX.

19. The SAW device of claim 1 wherein in the electrode stack, the first heavy metal layer is over the first conducting layer.

20. The SAW device of claim 19 wherein the electrode stack further comprises a second conducting layer over the first heavy metal layer.

21. The SAW device of claim 19 wherein the electrode stack further comprises:
a first adhesion layer between the first conducting layer and the piezoelectric substrate;
a barrier layer between the first conducting layer and the first heavy metal layer; and
a second adhesion layer over the first heavy metal layer.

22. The SAW device of claim 1 wherein in the electrode stack, the first conducting layer is over the first heavy metal layer.

23. The SAW device of claim 22 wherein the electrode stack further comprises a second heavy metal layer over the first conducting layer and formed from a heavy electrode material.

24. The SAW device of claim 22 wherein the electrode stack further comprises:
a first adhesion layer between the first heavy metal layer and the piezoelectric substrate;
a barrier layer between the first conducting layer and the first heavy metal layer; and
a second adhesion layer over the first conducting layer.

25. The SAW device of claim 1 wherein in the electrode stack, the first heavy metal layer is over the first conducting layer, and the electrode stack further comprises:
a second conducting layer over the first heavy metal layer;
a first adhesion layer between the first conducting layer and the piezoelectric substrate;
a first barrier layer between the first conducting layer and the first heavy metal layer;
a second barrier layer between the first heavy metal layer and the second conducting layer; and
a second adhesion layer over the second conducting layer.

26. The SAW device of claim 1 wherein in the electrode stack, the first conducting layer is over the first heavy metal layer, and the electrode stack further comprises:
a second heavy metal layer over the first conducting layer and formed from a heavy electrode material;
a first adhesion layer between the first heavy metal layer and the piezoelectric substrate;
a first barrier layer between the first conducting layer and the first heavy metal layer;
a second barrier layer between the second heavy metal layer and the first conducting layer; and
a second adhesion layer over the second heavy metal layer.

27. The SAW device of claim 1 wherein the piezoelectric substrate has a cut angle in the range of 0 to 50 degrees YX.

28. The SAW device of claim 27 wherein the piezoelectric substrate is formed from lithium tantalate.

29. A method for fabricating a surface acoustic wave (SAW) device, comprising:
providing a piezoelectric substrate; and
providing at least one electrode on a top surface of the piezoelectric substrate and formed from an electrode stack comprising a first heavy metal layer formed from a heavy electrode metal having a mass density higher than or equal to molybdenum and a first conducting layer formed from a conducting material stacked over one another.

30-36. (canceled)

37. The SAW device of claim 1 wherein the heavy electrode metal has a mass density higher than or equal 10.28 grams/cm³ .
